(19) United States
(12) Patent Application Publication
(10) Pub. No.: US 2016/0094072 A1
(43) Pub. Date: Mar. 31, 2016

(54) HYBRID ENERGY HARVESTING DEVICE

(71) Applicants: Yuanning Chen, Plano, TX (US); Wenzhang Wang, Arcadia, CA (US)

(72) Inventors: Yuanning Chen, Plano, TX (US); Wenzhang Wang, Arcadia, CA (US)

(21) Appl. No.: 14/497,770

(22) Filed: Sep. 26, 2014

(51) Int. Cl. H02J 7/00; H01L 31/028; H01L 31/053; H01L 31/18; H01L 31/0224; H01L 31/02; H02J 7/02; H02J 7/35; H01L 31/0216; H01L 31/068

(52) U.S. Cl. CPC H02J 7/0055; H01L 31/02168; H01L 31/028; H01L 31/053; H01L 31/068; H01L 31/022466; H01L 31/02021; H02J 7/025; H02J 7/35; H01L 31/1884; H01L 31/1864

(57) ABSTRACT

In one aspect, a hybrid energy harvesting device is presented that comprises a photovoltaic device having a substrate that forms a first side of the photovoltaic device. The substrate has a surface through which photons can pass to produce an electrical current within the photovoltaic device. An electrical storage device is located on a second side of the photovoltaic device that opposes the first side, and an antenna is located on one of the first or second sides of the photovoltaic device. The photovoltaic device and the antenna are electrically coupled to the electrical storage device.

### TECHNICAL FIELD

This application is directed, in general, to a hybrid energy harvesting device.

### BACKGROUND

An energy harvesting device is a device in which energy is derived or “harvested” from external ambient sources e.g. solar power, thermal energy, Vibrication, or radio frequencies (RF), captured, and stored for small, wireless, autonomous, low-energy electronic devices, such as sensors. The energy source for energy harvesters is present as ambient background, and thus, requires no exterior power source, thereby providing sufficient operational energy at no additional cost.

One type of energy harvesting device that has been widely used is a photovoltaic device (e.g., solar cells). These devices are used to harvest ambient light radiation and convert it to electrical energy. A separate, energy storage device, such as a capacitor or an electrochemical device (such as rechargeable battery or fuel cell), may be used in conjunction with the energy harvesting device in order to form a system to supply continuous power output and circumvent the problem of power interruption during periods of darkness, insufficient illumination, or under similar conditions. Often times other energy harvesting chip devices, such as radio frequency (RF) devices, piezoelectric devices, temperature gradient devices, or energy storage devices are often individually placed on the same printed circuit board (PCB) or printed wiring board (PWB) as the solar energy harvesting device. Additionally, an intelligent power management circuit may be employed between the various devices in order to obtain optimal charging efficiency and regulate battery discharge/charge activities.

### SUMMARY

One embodiment of the present disclosure provides a hybrid energy harvesting device. The hybrid energy harvesting device comprises a photovoltaic device having a substrate that forms a first side of the photovoltaic device. The substrate has a surface through which photons can pass to produce an electrical current within the photovoltaic device. An electrical storage device is located on a second side of the photovoltaic device that opposes the first side, and an antenna is located on one of the first or second sides of the photovoltaic device. The photovoltaic device and the antenna are electrically coupled to the electrical storage device.

Another embodiment comprises a photovoltaic device having a substrate that forms a first side of the photovoltaic device. The substrate has a surface through which photons can pass to produce an electrical current within the photovoltaic device. A capacitor is located on a second side of the photovoltaic device that opposes the first side, and an antenna is located on one of the first or second sides of the photovoltaic device. In this embodiment, the antenna has a “J” shape configuration or a “C” shape configuration, and the photovoltaic device and the antenna is electrically coupled to the capacitor.

Another embodiment provides a method of fabricating a hybrid energy harvesting device. The method comprises forming a photovoltaic device having a substrate that forms a first side of the photovoltaic device. The substrate has a surface through which photons can pass to produce an electrical current within the photovoltaic device. In another step, the method further comprises fabricating an electrical storage device on a second side of the photovoltaic device that opposes the first side. An antenna is formed on one of the first or second sides of the photovoltaic device. The antenna and the photovoltaic device are electrically coupled to the electrical storage device.

Another embodiment provides a sensor node. The sensor node comprises a circuit board, and a hybrid energy harvesting device that is located on and is electrically coupled to the circuit board. The hybrid energy harvesting device comprises a photovoltaic device having a substrate that forms a first side of the photovoltaic device. The substrate has a surface through which photons can pass to produce an electrical current within the photovoltaic device. An electrical storage device is located on a second side of the photovoltaic device that opposes the first side. An antenna is located on one of the first or second sides of the photovoltaic device. The photovoltaic device and the antenna is electrically coupled to the electrical storage device. This embodiment further comprises a solar conversion circuit that is located on and is electrically coupled to the circuit board to electrically couple the solar conversion circuit to the photovoltaic device and the electrical storage device. A radio frequency circuit is located on and is electrically coupled to the circuit board to electrically couple the radio frequency circuit to the antenna and the electrical storage device. A digital processing circuit is located on and is electrically coupled to the circuit board to electrically couple the digital processing circuit to the storage device.

### BRIEF DESCRIPTION

Reference is now made to the following descriptions taken in conjunction with the accompanying drawings, in which:

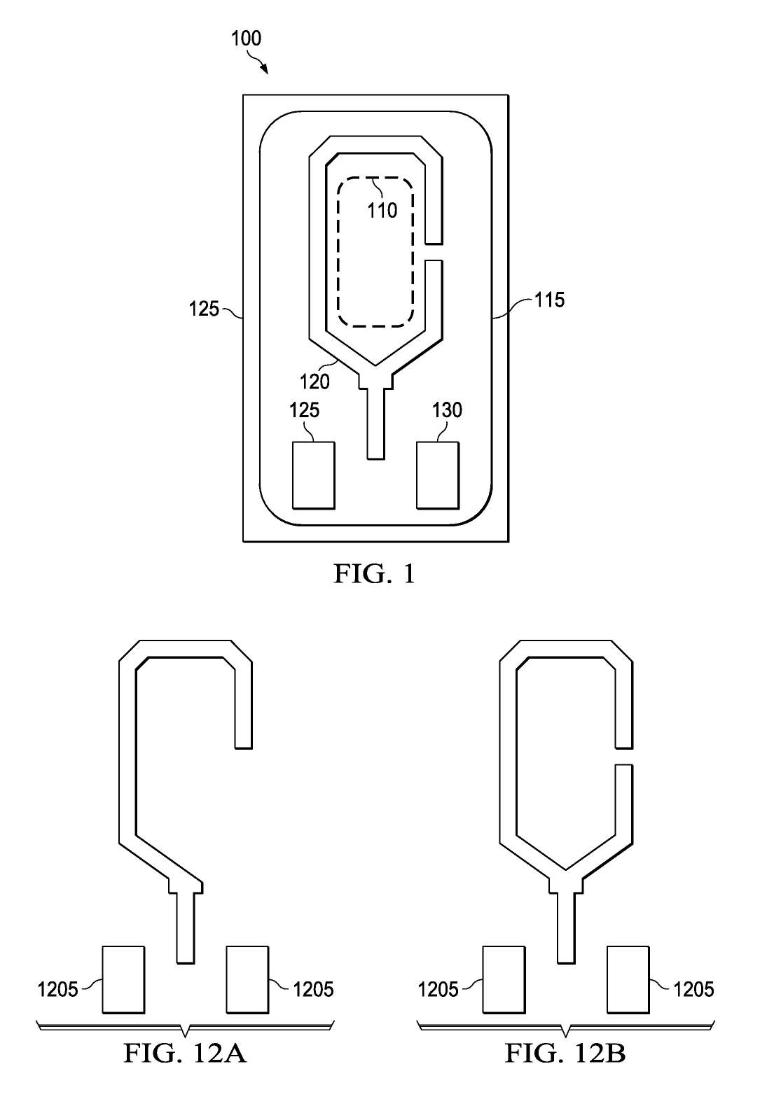

FIG. 1 illustrates an embodiment of a hybrid energy harvesting device as presented therein;

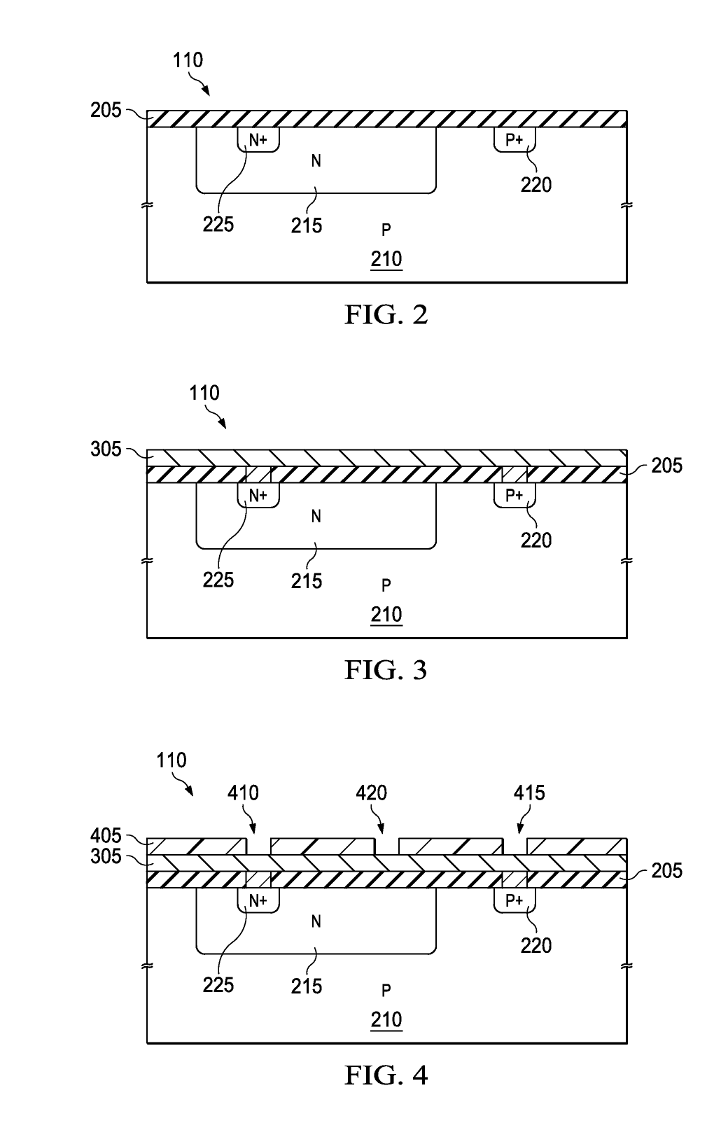

FIGS. 2-9 illustrate various fabricating steps involved in fabricating the energy harvesting device of FIG. 1, that includes a doped substrate;

FIG. 10 illustrates an energy harvesting device in which the antenna is located on the capacitor storage device;

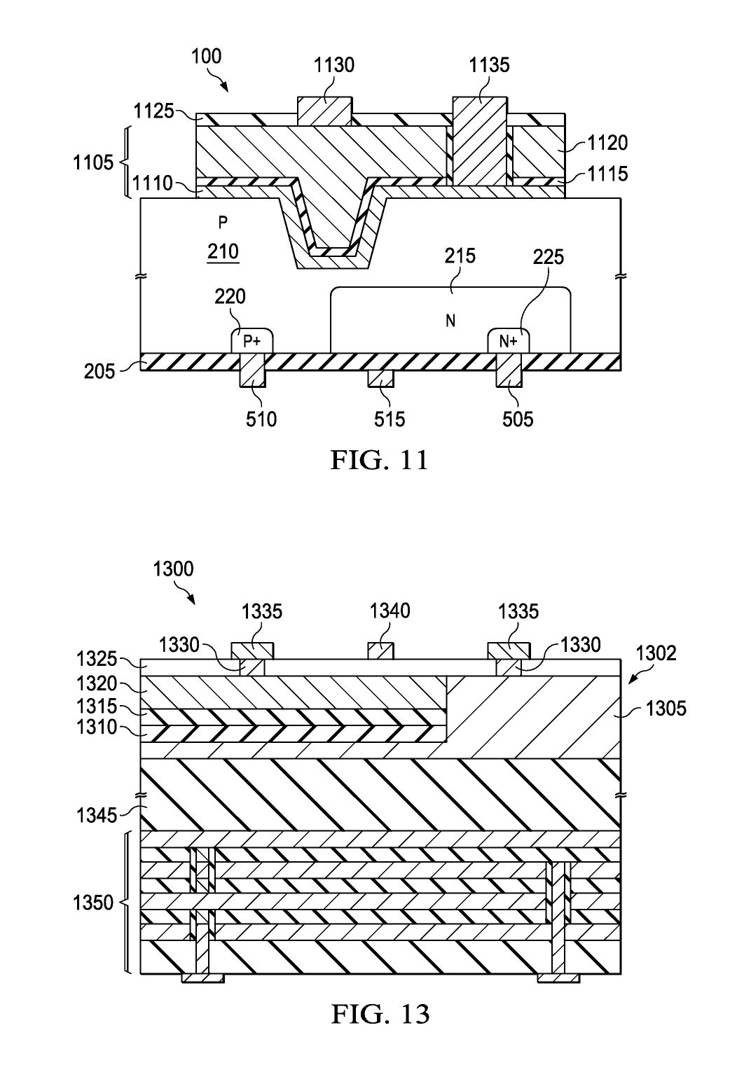

FIG. 11 illustrates an energy harvesting device in which the storage device is a trench capacitor;

FIGS. 12A-12B illustrate difference embodiments of an antenna that can be incorporated into the energy harvesting device of FIG. 1;

FIG. 13 illustrates an embodiment of the energy harvesting device constructed from thin film layers of cadmium sulfide and cadmium telluride and indium tin oxide;

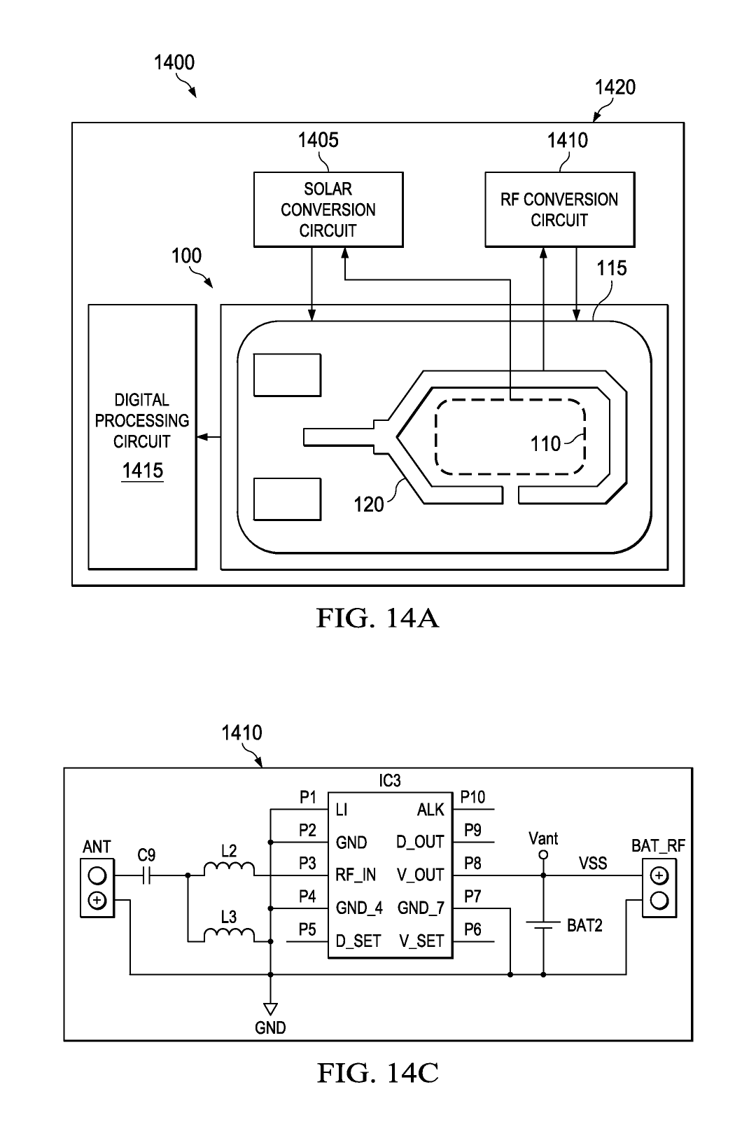

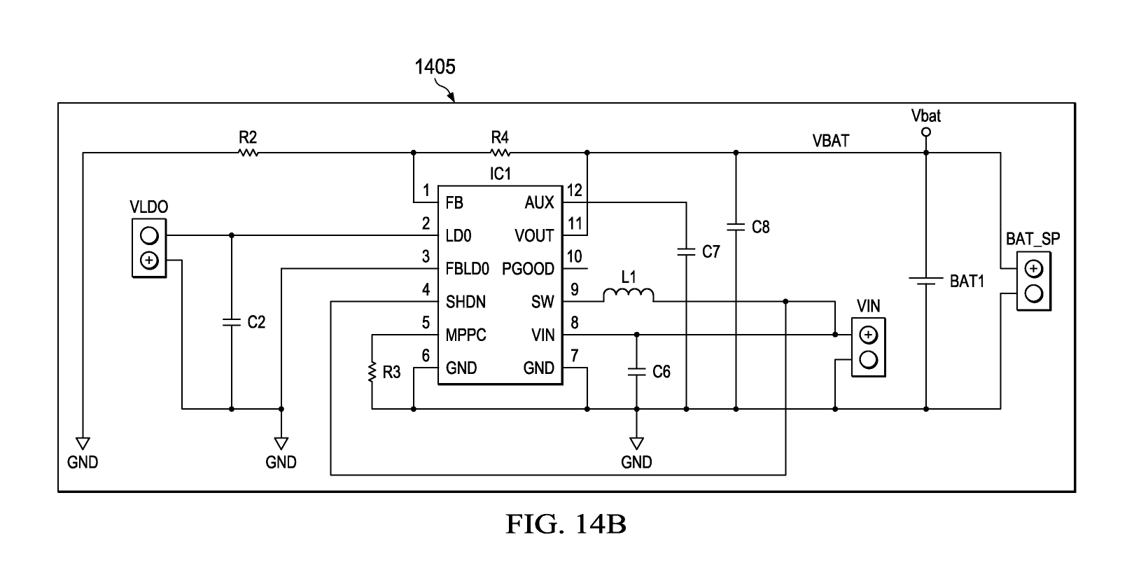

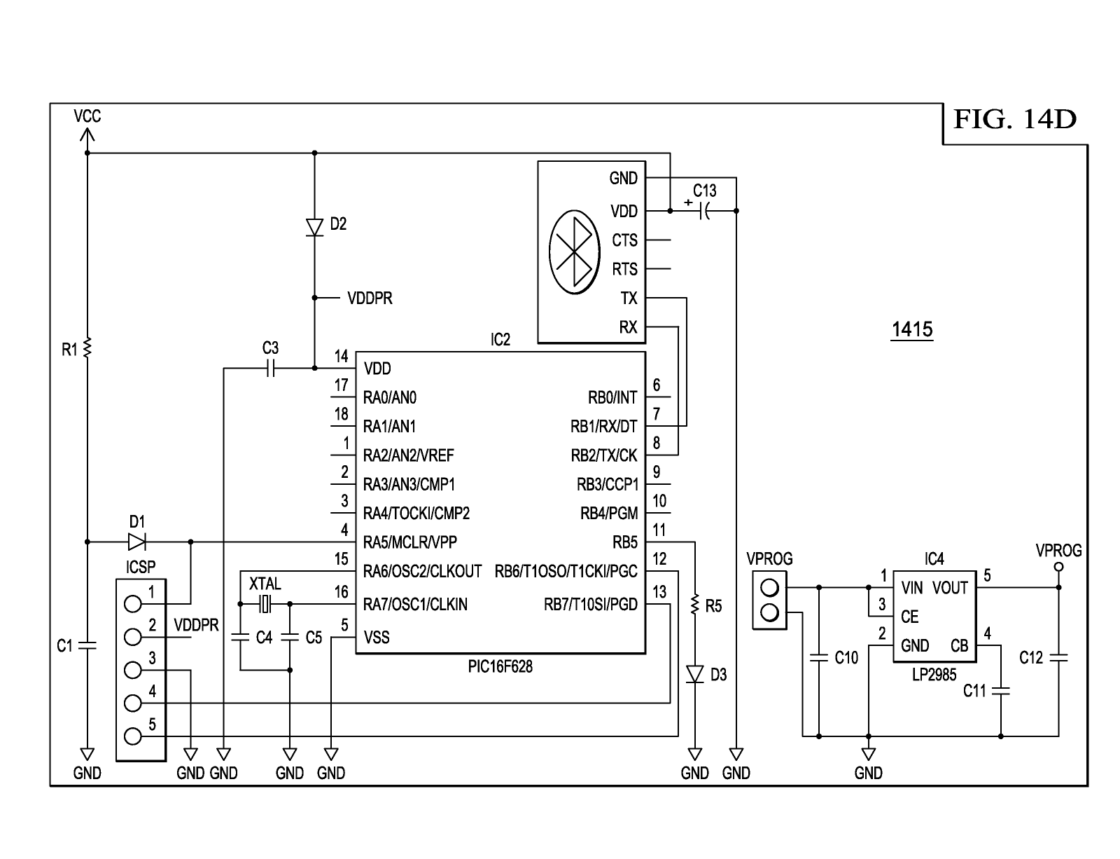

FIG. 14A illustrates a sensor node in which the energy harvesting device of FIG. 1 may be incorporated;

FIG. 14B illustrates an embodiment of a solar conversion circuit of FIG. 14A;

FIG. 14C illustrates an embodiment of a RF conversion circuit of FIG. 14A; and

FIG. 14D illustrates an embodiment of a digital processing circuit of FIG. 14A.

### DETAILED DESCRIPTION

The embodiments of this disclosure provide an integrated hybrid energy harvesting device. These embodiments uniquely disclose a photovoltaic device, which comprise a substrate, an energy storage device, and a RF antenna that are all located on the substrate that forms at least a portion of the photovoltaic device itself, as opposed to being separate chips that are individually located on different portions of a PCB or PWB. Though the photovoltaic device and the antenna capture different types of energy, they both store them in the energy storage device that is located on the same substrate that forms at least a portion of the photovoltaic device itself. With these separate devices all being integrated into a unitary device, energy transfer efficiencies are improved, along with a reduction in manufacturing costs when compared to individually manufacturing the different devices on separate chips. This unique unitary configuration also allows for a reduction in size, thereby providing additional space on a PCB or PWB for other or additional components.

FIG. 1 illustrates one embodiment of the integrated energy harvesting device 100. This embodiment generally illustrates the energy harvesting device 100 that comprises a photovoltaic device 110, a storage device 115, and an antenna 120 having ground planes 125 and 130 electrically coupled thereto. The photovoltaic device 110, the storage device 115 and the antenna 120 are electrically couplable to other components as described below. All three devices are located on the photovoltaic substrate 125 that forms a portion of the photovoltaic device 110, itself, which eliminates the need for separate chipped devices and presents a more compact integrated structure.

FIGS. 2-10 illustrate various fabrication steps that may be used to construct one embodiment of the energy harvesting device 100 of FIG. 1. FIG. 2 illustrates an intermediate step in which an antireflection layer 205 is formed on a conventional substrate 210, such as silicon, polysilicon, or amorphous silicon. The antireflection layer reduces the amount of reflection that might otherwise occur, and thus, increases the amount of light that enters the photovoltaic device 110 of FIG. 1. In one embodiment, the substrate 210 may be doped with an n-type or p-type background dopant, such as boron, boron fluoride, phosphorous, arsenic, or other known dopants. Additionally, the doped substrate 210 may also have oppositely doped tub regions 215, 220 located therein. In the illustrated embodiment, an n-tub region 215 is formed within the substrate 210 that has been doped with a p-type background dopant. A heavily doped contact region 225 that is doped with the same type dopant as the n-tub region 215 is located within the n-tub region 215. The heavily doped contact region 225 may have a dopant concentration that ranges from about e19 to about e21. Tub region 220 is also a heavily doped p-tub that serves as an oppositely doped, second contact region for the device and may have a dopant concentration that ranges from about e19 to about e21. The oppositely doped regions within the substrate form a p-n junction within the photovoltaic device 110 of FIG. 1. Conventional processes, such as ion implantation or solid phase diffusion, may be used to dope the substrate 210 in the way generally shown in FIG. 2.

Conventional materials and processes may be used to deposit or otherwise form the antireflection layer 205. For example, in one embodiment, the antireflection layer 205 may be a dielectric layer comprised of a silicon nitride, silicon dioxide, or indium tin oxide (ITO). Also, in certain embodiments, the surface of the antireflection layer 205 may be roughened to further inhibit any reflection of light from the photovoltaic device 110.

FIG. 3 illustrates another intermediate step of fabrication of the photovoltaic device 110 of FIG. 1. In this step, a conventional lithographic process may be used to pattern the antireflective layer 205 to form photovoltaic cell contact openings in the antireflective layer 205. Following the formation of the contact openings, conventional deposition processes, such as chemical vapor deposition, physical vapor deposition or thermal evaporation, may be used to deposit or otherwise form a metal layer 305 over the antireflective layer 205 and within the contact openings, as shown in the embodiment of FIG. 3. It should be understood that barrier layers, though not shown may be first deposited to form any barrier layers that might be necessary to prevent unintended diffusion between the antireflective layer 205 and metal layer 305. The metal layer 305 may be comprised of conventional conductive metals and alloys thereof, such as aluminum, copper, gold, or silver.

FIG. 4 illustrates the photovoltaic device 110 of FIG. 3 after the conventional deposition and patterning of a photoresist layer 405, in which photovoltaic contact openings are formed, 410 and 415, and an antenna opening 420.

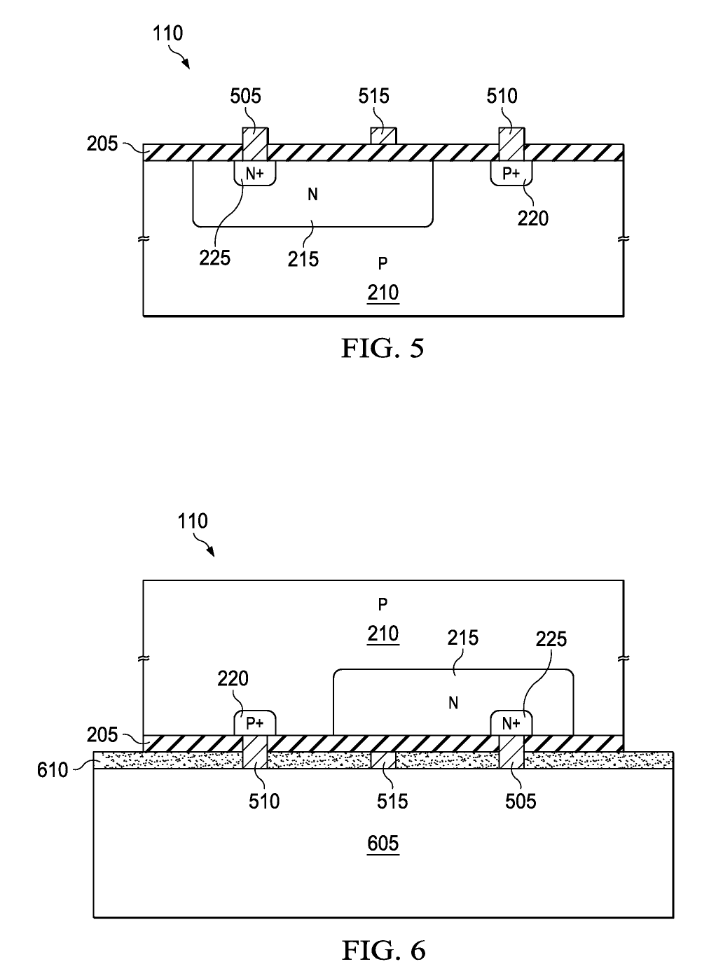

FIG. 5 illustrates the photovoltaic device 110 of FIG. 4 after the conventional removal of the photoresist layer 405 and the conventional etching of the metal layer 305. The etching process completes the formation of photovoltaic contact 505 that contacts the n-type contact 225, photovoltaic contact 510 that contacts the p-type contact 220, and completes the formation of the antenna 515. As seen in this step, the antenna is formed on top of the dielectric antireflective layer 205, which provides proper isolation of the antenna from the underlying n-type tub 215. In alternative embodiments, which are discussed below, it should be noted that the antenna 515 may also be formed by using an inkjet process, as opposed to the patterning and deposition process, as just discussed.

As shown in FIG. 6, after the formation of the photovoltaic contacts 505 and 510 and antenna 515. In one embodiment, the substrate 210 of the photovoltaic device 110 is attached to a conventional carrier substrate 605 with an adhesive 610, such as an epoxy. After attaching the substrate 210 to the carrier substrate 605, if needed, the unattached side (i.e., backside) of the substrate 210 may be thinned in preparation of the formation of the storage device.

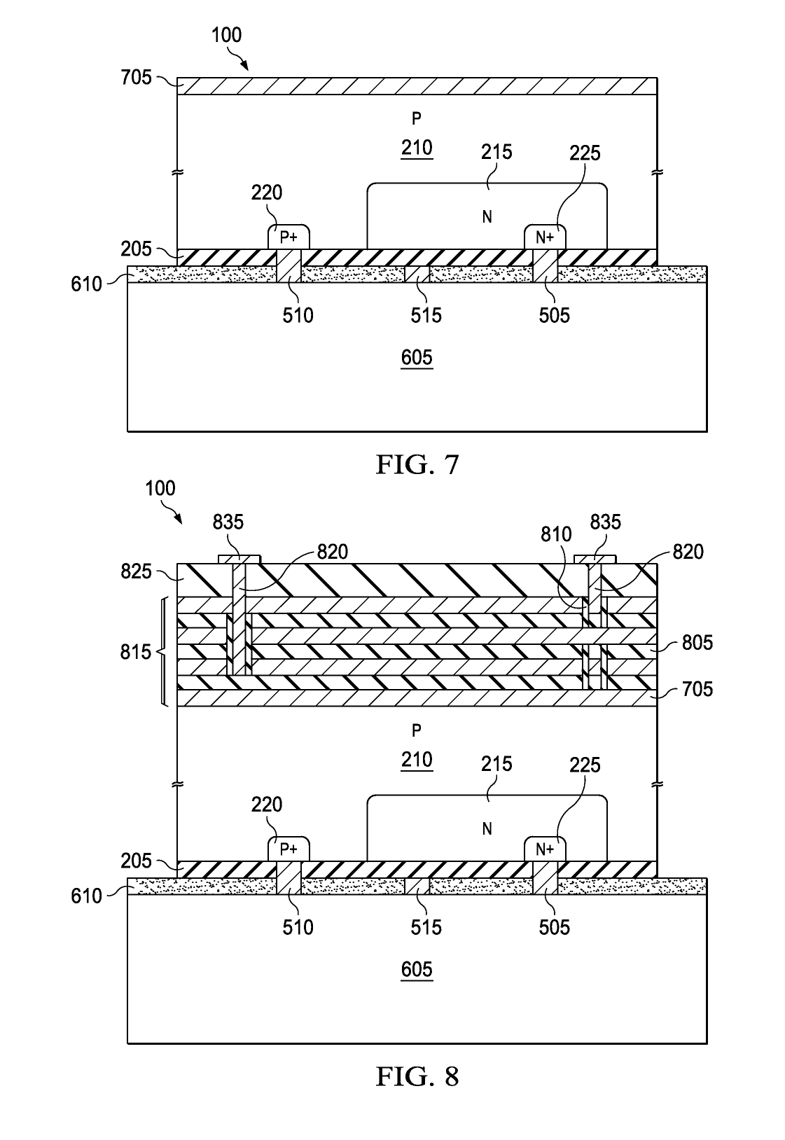

FIG. 7 illustrates one embodiment of the photovoltaic device 110 of FIG. 6, after the deposition of a first electrode 705 of the storage device 115. In this particular embodiment, the storage device 115 is a capacitor. However, in alternative embodiments, the storage device 115 may be an electrochemical thin film battery and other types of storage devices, and those skilled in the art, given the present disclosure, would understand how to fabricate these alternative storage devices. Conventional materials and deposition processes may be used to deposit the various layers of the storage device 115. For example, the first electrode 705 may be comprised of tungsten, copper, titanium nitride, conductive silicides, such as cobalt silicide, and other conventional capacitor electrode materials.

FIG. 8 illustrates the embodiment of FIG. 7, after the conventional deposition of alternate conductive layers 705 and dielectric layers 805, including side wall isolation regions 810, which completes the formation of the capacitor 815. As seen in this embodiment, the capacitor 815 also includes vias 820 that extend through the portions of the capacitor 815 to provide electrical connectivity through the capacitor 815. A conventional capping layer 825 is also provided in this embodiment, in which conventionally formed outer connecting vias 830 and contact pads 835 connect to the capacitor vias 820 to provide external, electrical connection to the capacitor 815. In the illustrate embodiment, the capacitor 815 has a stacked configuration. However, in other embodiments, as shown below, the capacitor may be a trench capacitor. After the formation of the capacitor 815, an annealing process may be conducted to anneal out defects within the device. In one embodiment, a rapid thermal anneal may be used. However, in another embodiment, a laser anneal may be used. The laser anneal provides the advantage of rapidly heating the energy harvesting device 100, but at the same time limiting high temperature effects on other heat-sensitive components that can be present within the device.

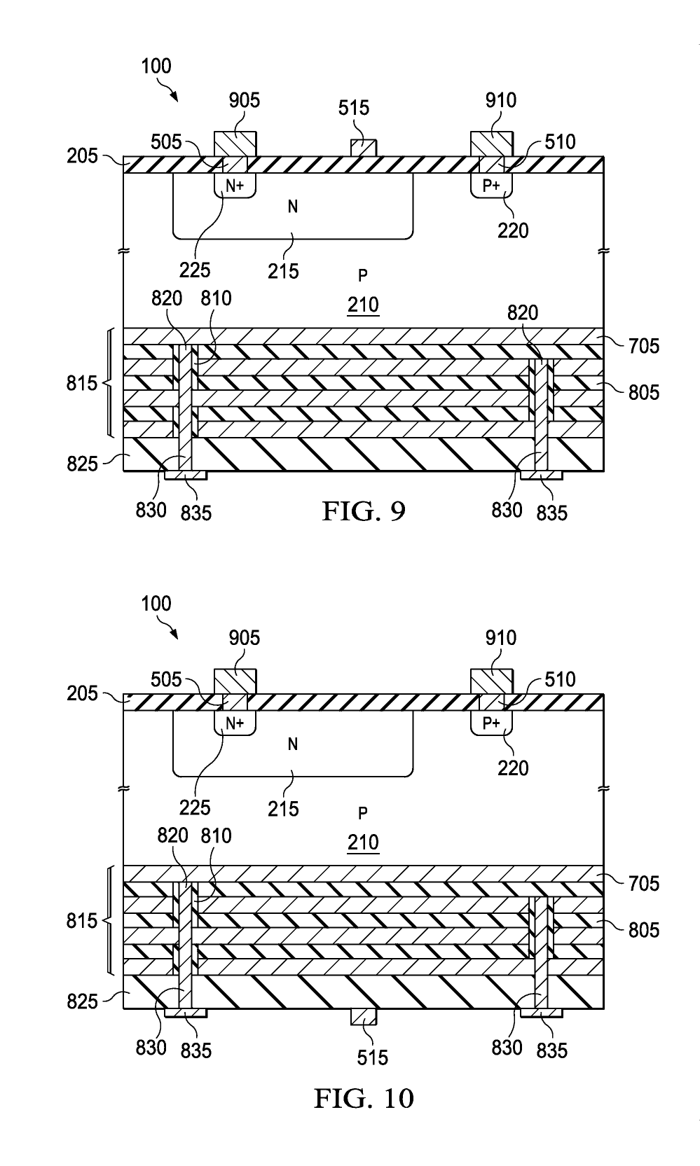

After the annealing process is complete, the carrier substrate 605 is removed, which results in the completed energy harvesting device 100, as illustrated in the embodiment of FIG. 9. Also illustrated in this embodiment are shown contact pads 905, 910 that electrically connect to photovoltaic contacts 505 and 510, respectively.

FIG. 10 illustrates another embodiment of the energy harvesting device 100, with the exception that the antenna 515 is located on the outer surface of the capacitor 815. The process as explained above can be used to form the various components, except when forming the antenna. In this embodiment, the antenna would not be patterned into the metal layer 305, as shown in FIG. 4, but instead would be patterned and formed at the same time as the contact pads 835.

FIG. 11 illustrates another embodiment of the energy harvesting device 100 in which the storage device 115 (FIG. 1) is a high energy trench capacitor 1105. A complementary pathway to achieve high energy-density storage in a capacitor is by increasing its active area as much as possible. Here, high aspect ratio 3-D structures, associated with the trench capacitor 1105, provide a potential solution to increase the area of a capacitor up to four times by taking advantage of the sidewalls of the trench capacitor 1105. These devices provide efficient energy storage for a wide range of applications, including small-sized portable systems. One of the most attractive features of these types of capacitors is their ability to perform a large number of charge/discharge cycles without compromising the device's lifetime. For example, assuming the energy harvesting device 100 is going to operate on stand-by mode (approximately 100 nA at 3.3 V) and activate every certain time to collect/transmit data, an energy storage unit capable of supplying a steady voltage for one second is sufficient to allow the sensor-microcontroller-transmitter unit to operate since data collection, processing and transmission tasks only require tens of milliseconds. Embodiment of the trench capacitor 1105 has provided herein achieves this goal.

The trench capacitor 1105 comprises a first, or bottom, electrode layer 1110. In one embodiment, the trench capacitor 1105 may be formed on a Si wafer using reactive ion etching (RIE) with C₄F₈ followed by SF₆. The depth of the trench may be about 150 μm. In one embodiment, the electrode 1110 may be deposited by deposing a 200 nm of layer of cobalt followed by the deposition of a 200 nm of TiN. Conventional sputter deposition processes may be used to form each of these layers. The TiN layer acts as a capping layer to prevent further oxidation during processing. The deposition of the electrode 1110 may be then be annealed in two steps, at 550° C. for 30 seconds and at 780° C. for another 30 seconds in a rapid thermal annealing (RTA) system to form, in one embodiment, a cobalt silicide (CoSi₂) layer within the trench. In other embodiments, the electrode layer 1110 may comprise other conventional conductive silicide materials or conductive metals, such as those mentioned above regarding the stacked capacitor 815.

A dielectric layer 1115 is located on the first electrode 1110. Preferably, the dielectric layer 1115 is a high k dielectric material, such as hafnium oxide, tantalum oxide, after which the second or top electrode 1120 is formed. In one embodiment, the dielectric layer 1115 was fabricated by synthesizing a 60 nm layer of HfO₂ by atomic layer deposition (ALD). In an alternative embodiment, dielectric layer was formed using Al₂O₃/TiOₓ nanolaminates (TAO-NLs) with an Al₂O₃ interfacial layer at the electrode/nanolaminate interface. A 20 nm TAO-NL was deposited by atomic layer deposition (ALD) at 250° C. on CoSi₂ (bottom electrode 1110) using trimethylaluminum [Al(CH₃)₃] and titanium tetrachloride (TiCl₄) as Al and Ti precursors and H₂O as the oxidant. In addition, a 10 nm of Al₂O₃ was deposited on top of the TAO-NLs to reduce the dielectric loss and leakage current, which is also beneficial in high performing energy storage/super capacitor devices. In those embodiments where the TAO-NL dielectric layer is used, it is expected that a dielectric constant of approximately 100, which is almost 10× higher than for other dielectrics, can be achieved. Additionally, the low temperature TAO-NL deposition makes the process compatible with low-cost integrated energy harvesting technology, as presented herein.

The top electrode 1120 may be fabricated using conventional processes and materials and may comprise a conductive metal. In one embodiment, the top electrode may be an aluminum layer having a thickness of about 200 nm and may be deposited by e-beam evaporation. The trench capacitor 1105 also includes a capping layer 1125, which may be comprised of a conventionally deposited layer of silicon oxide or silicon nitride, and contact vias 1130 and 1135.

In certain embodiments, the antenna, as generally discussed above, may have a general “J” shape or “C” shape geometric configuration that is, they look like, or are similar in physical appearance, to the English alphabetic letters J and C. Examples of these “J” and C” shaped antennas are shown in FIGS. 12A-12B. The “J” shaped antenna is generally represented by FIG. 12A, while the “C” shaped antenna is generally represented by FIG. 12B. Each antenna configuration include ground plates 1205 located on either side of each of the antennas. In one preferred embodiment, the antenna as a “C” shape geometric configuration. This particular embodiment provides the advantage of an antenna that is capable capturing RF signals ranging from about 900 MHz to about 2.4 GHz and converting the RF signals into electrical energy.

As mentioned above, in addition to conventional lithographic processes, the antenna uniquely may be deposited and patterned by using a low temperature inkjet printing process. Low temperature processes can be very beneficial for multiple device integration in that the lower temperatures reduce unintended damage to other temperature sensitive portions of the device. In one embodiment, a silver, or other metal-based inks are used to print the antenna configuration. Such inkjet printing processes have the advantages of low time cycle and use less material compared to other conventional processes, such as photolithography, screen printing, and electro-deposition. Moreover, the inkjet printing process can generate accurate pattern without ink spreading or spilling on a wide range of low-cost substrates such as silicon, silicon, and plastics.

As one example, inkjet printing deposition can be carried out using an Omnijet100 inkjet printer from Unijet Co., Ltd. and Nano Silver Ink “SilverJet DGP-45HTG” from Advanced Nano Products (ANP). The cartridge of the inkjet printer may be filled with 1.5 mL of the silver ink, and in such instances, the volume deposited for a single layer antenna deposition may be approximately 120 nL.

When silicon is used, the substrate is pre-cleaned with acetone followed by isopropyl alcohol (IPA) and de-ionized water for 5 minutes each in an ultrasonic bath and then blown with N2 to dry. The antenna may be formed by printing single metal strips arrays. Another advantage to this inkjet printing processes is that is allows for more precise control of dimensional aspects of the antenna, which makes the desired film resistance more easily and accurately to obtain.

The inkjet process as provided herein may be varied to optimize the antenna's physical dimensions. Since the inkjet printing process is quick and relatively inexpensive, more antenna designs and sample may be quickly fabricated and test to reach the desired overall design.

In one embodiment, the antenna may be printed one layer at a time and sintering it at 430° C. for 1 hour, followed by printing layer two. In another process, the antenna may be formed by printing all layers before sintering all the layers at 430° C. for 1 hour at the same time. In yet another embodiment, a first layer may be printed, then sintered at 150° C. for 1 hour, after which the next layer is printed and sintered at 150° C. for 1 hour and so on, until after the final layer printing, which is sintered at 430° C. for 1 hour.

In another embodiment, the antenna may be printed on a polyethylene naphthalate (PEN) substrate using a low sintering temperature nano silver ink (DGP 40LT-15C, from ANP) with a lower sintering temperature ranging from about 120 to about 150° C.) for about 1 hour, since PEN sheets can tolerate a temperature up to 155° C. without being de-shaped.

In one embodiment, the 915 MHz single frequency energy harvesting antenna is a quarter wavelength metal strip monopole antenna printed on a dielectric substrate. In order to reduce the antenna size, the printed strip can be folded to the above-mentioned “J,” as shown in FIG. 12A. The antenna feed is a section of 50 ohm microstrip line where the back side of this portion of the dielectric board is fully metalized. By adjusting the strip width and length, the antenna can be impedance matched to 50 ohm at the desired frequency, i.e., 915 MHz. For dual frequency antenna for 915 MHz and 2.45 MHz, an extra length of strip line is added to the folded monopole as shown in FIG. 12B to achieve the above-mentioned “C” shape design. In this configuration, the antenna structure can be tuned to resonant at both frequencies with good impedance matching. For the 915 MHz RF signal, the return loss may range from about −8.1 dB to about −15.8 dB. The “C” shaped design can generally result in an optimized antenna structure for better signal absorption at 915 MHz compared to “J” shaped antenna. However, the “J” shaped design on a PCB substrate has better performance at 915 MHz. It is believed that this high performance of the “J” shaped antenna design on a PCB substrate may be possibly due to the lower resistance from the electrodeposited thick metal, which directly modifies the input impedance of the antenna and positions the minimum peak (−16.9 dB for 935 MHz) very close to 915 MHz, while the minimum peak for the “C” shaped antenna design is at −21.2 dB for 935 MHz, which is farther away from the 915 MHz frequency. Therefore, there is more room for optimization by modifying the input impedance of the “C” shaped design, by adjusting the film resistance to reach approximately −21.2 dB 915 MHz and obtain similar performances as other conventional antennae.

For 2.4 GHz RF signal absorption, the good performance can be achieved by using the “C” shaped and “J” shaped antenna designs with −4.3 dB and −5.2 dB, respectively. However, higher signal absorptions at this particular frequency can be achieved by tuning the antenna to reach the minimum return loss peak (−17.2 dB at 2.12 GHz). It has been presently found that the “C” shaped design is an optimized antenna design for energy harvesting/charging at 915 MHZ and 2.4 GHz dual frequencies.

FIG. 13 illustrates another embodiment of an integrated photovoltaic device 1300. In this embodiment, the photovoltaic portion 1302 is comprised of thin film materials as opposed to a doped substrate, such as the embodiments described above. In one embodiment, the device 1300 is comprised of a conductive metal layer 1305, such as gold, silver, copper, or alloys thereof, over which is deposited a cadmium telluride (CdTe) layer 1310. A cadmium sulfide (CdS) layer 1315 is located on the CdTe layer 1310. An oxide layer, such as indium tin oxide (ITO) layer 1320 is located over the CdTe layer 1315, and a substrate layer 1325 is located on the ITO layer 1320 and a portion of the metal layer 1305, as shown. Contact vias 1330 are located in the in the substrate layer 1325 and contact pads 1335 are located on the vias 1330. In this embodiment, an antenna 1340 is located on the insulating substrate layer 1325.

A conventionally deposited dielectric layer 1345 is located on the back side of the metal layer 1305 that provides a substrate on which a capacitor 1350 and associated structures, as the ones described above may be located. It should be noted that, in alternative embodiments, the antenna 1340 may be located on the capacitor 1350.

The CdTe/CdS layers 1310, 1315 form p-n junctions within the device and are very suitable for the present integrated device, due to their compatibility with low-cost and compatible deposition methods. For example, pulsed laser deposition (PLD), close space sublimation (CCS) and chemical bath deposition (CBD) techniques may be used to fabricate the CdTe/CdS layers 1310, 1315 and the substrate layer 1325. The substrate layer 1325 serves as the contact for the cathode, while the metal layer 1305 is used as top contact for the anode.

The small bandgap of CdTe (approximately 1.5 eV) makes the material suitable to absorb most of the solar radiation. In theory, once the radiation is absorbed, the electron-hole pairs that are generated in the material are swept to the electrodes by the electric field generated at the junction. Therefore, the overall characteristics of the solar portion of the photovoltaic device 1300 are determined by the quality of the p-n junction.

To evaluate and obtain an optimal p-n junction, 800 nm of CdTe may be deposited in-situ on top of 50 nm of CdS using a Neocera PLD, which is a deposition method that obtains a high quality and uniform film. Since CdS is used as a seeding layer for the junction (CdTe on top), the electrical properties of the p-n diode are evaluated in terms of different CdS deposition conditions: deposition pressure, deposition temperature and post-annealing treatments, while maintaining the CdTe under the same conditions.

In one embodiment, the deposition temperature for CdS may be approximately 200° C. followed by a post-anneal of about 200° C. yields high Iₒₙ/I_{off} ratios, which may range from about 10⁴ to about 10⁵. A low reverse current device may be obtained by depositing the CdS layer 1315 at a pressure of about 40 mTorr, and 220° C., while varying the post-anneal temperature. This results in a high Iₒₙ/I_{off} ratio. Post-annealing is beneficial to decrease the reversed bias leakage current and improve the diode-like behavior. For example, the Iₒₙ/I_{off} ratio increases as the post-annealing increases.

The thickness of the CdTe layer 1310 may be at least 1 μm of CdTe to absorb most of the solar radiation to increase the device's 1300 efficiency. Thicker films (>1 μm) may be problematic to obtain with PLD techniques. In such instances, other methods, such as close space sublimation (CSS), can be used. CSS is a simple and low-cost deposition technique compatible with large area substrates.

In order to have the possibility of obtaining thicker CdTe films with CSS methods, three different CdTe deposition processes can be used, examples of which follows:

CdTe−PLD: this process utilizes 1.5 μm of CdTe deposited by PLD, as described above.

CdTe−CSS: during this process approximately 1.5 μm of CdTe can be deposited using CSS on top of the CdS previously deposited by PLD.

CdTe−PLD+CSS: this hybrid deposition technique involves a thick CdTe−CSS film deposited on top of a previously defined CdS/CdTe junction deposited by PLD. CdTe−PLD (130 nm) may be used as seed layer to deposit the CdTe−CSS (1.5 μm).

Photovoltaic devices fabricated using only PLD result in the highest efficiency (>2%) due to the high quality p-n junction formed from the in-situ depositions. The high quality interface between the CdS and the CdTe can be achieved by preserving the device under vacuum during fabrication processes until the junction is completely formed.

In one advantageous fabrication processes, the ITO substrate layer 1325 is patterned for 3 mm×3 mm devices by conventional photolithography process and etched with hydrochloric acid etchant at room temperature for 10 minutes. CdTe/CdS in-situ deposition by PLD involves ramping the substrate temperature to about 220° C., using a ramp rate of about +/−10 C/min. and at a frequency of about 10 Hz. For CdS, the deposition pressure is about 40 mTorr in an argon atmosphere until a thickness of about 50 nm is achieved. For CdTe, the deposition pressure is about 20 mTorr in an argon atmosphere until a thickness of about 1.5 μm is achieved.

Once the CdS/CdTe films are formed, the device may be treated with CdCl₂ by drop casting a CdCl₂-methanol solution, followed by anneal at about 400° C. for about 30 min. in a nitrogen atmosphere. The metal layer 1305, such as a gold/copper stacked layer, may be deposited by electron beam followed by an anneal at about 150° C. for about 30 minutes in a nitrogen atmosphere. The dielectric layer 1325, such as a silicon dioxide layer may be conventionally formed using a PECVD process.

The above described embodiment of the processing flow is compatible with the inkjet processes used to fabricate the RF antenna, as described above. It should be noted that the deposition and annealing temperatures from both devices (antenna and photovoltaic cell) are compatible with each other.

In another fabrication embodiment of achieving the integrated photovoltaic device as shown in FIG. 13, the substrate 1325 is conventionally attached to a carrier substrate as previously described regarding other embodiments. The ITO layer 1320 is then deposited and patterned on the substrate 1325 to define an active area (i.e., p-n junction area) for the device 1300. Following this about a 70 nm thick CdS layer 1315 is deposited only on the patterned side of the ITO layer 1320. On top of the CdS layer, a thick CdTe layer 1310 having an approximate thickness of about 1.5 μm is deposited by closed space sublimation (CSS) system followed by a CdCl₂-methanol deposition using drop-casting. An anneal is conducted for about 30 minutes in a nitrogen gas atmosphere inside a glovebox at about 400° C. After the CdS/CdTe deposition of layers 1315, 1310 on the ITO layer 1320, a silicon dioxide layer is conventionally deposited on the metal layer 1305 to a thickness sufficient for forming the capacitor 1350, which can be achieved in the same manner as in the above-described embodiments.

Following the formation of the capacitor 1350, the metal contact vias 1330 are formed using conventional deposition process. Preferably, the metal is a highly conductive metal, such as aluminum, gold, silver, copper or alloys of these metals. However, other known conductive materials may also be used. The contact pads 1335 may be formed using conventional depositional and lithographic processes, or they may be formed using the above-described inkjet process. For example, gold/copper contacts may be deposited by e-beam evaporation using shadow mask to thicknesses of about 200 nm and 3 nm, respectively. Finally, after the contact deposition, the whole integrated solar cell-antenna device was sintered again at 150° C. for 30 minutes in N₂ to improve the contacts of solar cell.

In a preferred embodiment, the antenna 1340 is printed, using the above-described inkjet method, on the surface of the substrate layer 1325 located on the photon receiving-side of the photovoltaic device 1300, as shown in FIG. 13. Alternatively, the antenna may also be formed using conventional deposition and lithographic processes. The antenna 1340 is printed in such a way it not obstruct the photons that need to enter into the active regions (CdS/CdTe layers 1315, 1310) of the photovoltaic device 1300. DGP 40LT-15C nano silver ink is used to print the antenna 1340. After printing, the antenna 1340 was sintered at 150° C. for about 30 minutes in a nitrogen atmosphere. The rest of the sintering was performed after depositing the metal contacts for the solar cell.

FIG. 14A illustrates an embodiment of a sensor node 1400 in which the integrated photovoltaic device of 100 of FIG. 1 may be used. In this embodiment, the sensor node 1400 is a temperature sensor node that includes a solar conversion circuit 1405 that is connected to the photovoltaic solar portion 110 (FIG. 1) of the integrated photovoltaic device 100. The solar conversion circuit 1405 converts the solar energy into electric energy and then transmits it to the storage device 115. The sensor node 1400 further includes a RF conversion circuit 1410 that converts RF signals into electrical energy and then transmits it to the storage device 115. A digital processing circuit 1415 can then draw on power from the storage device 115 to perform the sensing function of the sensor node 1400. As shown in the illustrated embodiment, all of these above-mentioned components are located on a common a circuit board 1420, such as a PWB or PCB. In one embodiment, each of these components 100, 1405, 1410, and 1415 are located on separate printed circuit boards that are electrically coupled to the common board 1420.

FIG. 14B illustrates a commercially available example of the solar conversion circuit 1405, which in the illustrated embodiment is a LTC3105 circuit. The LTC3105 is a high efficiency step-up DC/DC converter that can operate to form input voltages as low as 225 mV. This start-up capability and integrated maximum power point microcontroller (MPPC) enables operation directly from low voltage, high impedance alternative power sources, such as photovoltaic cells. The AUX powered 6 mA LDO provides a regular rail for external microcontrollers and sensors while the main output is charging.

FIG. 14C illustrates a commercially available example of the RF conversion circuit 1410, which in the illustrated embodiment is a Powercast, P1110, power harvester receiver that receives and converts RF to DC. The RF conversion circuit 1410 provides RF energy harvesting and power management for the energy storage device 115, and also provides the energy to the attached storage device 115 that is to be stored. When an adjustable voltage threshold on the storage device 115 is achieved, the RF conversion circuit 1410 automatically disables the charging function. Some advantages associated with the illustrated RF conversion circuit 1410 are lower power consumption, higher conversion efficiency, (>70%), and operation form 0V to support capacitor recharging.

FIG. 14D illustrate a commercially available example of the digital processing circuit 1415, which in the illustrated embodiment, is a PIC16F628A microcontroller from Microchip. It is an 18-pin flash, low cost, high performance, CMOS, fully static, 8-bit microcontroller, and has the following advantageous features: analog comparators for the temperature conversion circuit, and addressable universal synchronous/asynchronous receiver/transmitter USART, which allows serial communication with a wireless Bluetooth module (not shown). It should be noted that this circuit will work at 3V, but for the ICSP programming 5V are required. For that reason, a 9V battery, which is regulated by a L2985 regulator, may be attached.

Those skilled in the art to which this application relates will appreciate that other and further additions, deletions, substitutions and modifications may be made to the described embodiments.

What is claimed is:

1. A hybrid energy harvesting device, comprising:
a photovoltaic device having a substrate that forms a first side of said photovoltaic device, said substrate having a surface through which photons can pass to produce an electrical current within said photovoltaic device;
an electrical storage device located on a second side of said photovoltaic device that opposes said first side; and
an antenna located on one of said first or second sides of said photovoltaic device, said photovoltaic device and said antenna electrically coupled to said electrical storage device.

2. The hybrid energy harvesting device of claim 1, wherein said substrate is a doped silicon substrate doped with opposite dopants to form oppositely doped tub regions and a p-n junction in said doped silicon substrate, and further comprising an antireflective layer located on said surface and having first and second electrical contacts formed therein that contact said oppositely doped tub regions, respectively.

3. The hybrid energy harvesting device of claim 1, wherein said storage device is a capacitor and said antenna is located on an outer surface of said capacitor.

4. The hybrid energy harvesting device of claim 3, wherein said capacitor is a trench capacitor that includes a capacitor dielectric layer comprising Al₂O₃/TiOₓ nanolaminate.

5. The hybrid energy harvesting device of claim 1, wherein said antenna has a “J” shape or a “C” shape configuration.

6. The hybrid energy harvesting device of claim 5, wherein said antenna has said “C” shape configuration, which allows said antenna to receive radio frequency (RF) signals ranging from about 915 MHz to about 2.4 GHz and convert said RF signals into an electrical current.

7. The hybrid energy harvesting device of claim 1, wherein said photovoltaic device comprises layers of cadmium sulfide (CdS) and cadmium telluride (CdTe) located over said substrate.

8. The hybrid energy harvesting device of claim 7, further comprising a low resistivity transparent conductive oxide (TCO) layer located on said substrate, a cadmium sulfide (CdS) layer located on said TCO layer, a cadmium telluride (CdTe) layer located on said CdS layer, and a metal layer located on said CdTe layer.

9. The hybrid energy harvesting device of claim 8 further comprising a dielectric layer located on said metal layer, and wherein said energy storage device is located on said dielectric layer.

10. A method of fabricating a hybrid energy harvesting device, comprising:
forming a photovoltaic device having a substrate that forms a first side of said photovoltaic device, said substrate having a surface through which photons can pass to produce an electrical current within said photovoltaic device;
fabricating an electrical storage device located on a second side of said photovoltaic device that opposes said first side;
forming an antenna located on one of said first or second sides of said photovoltaic device; and
electrically coupling said antenna and said photovoltaic device to said electrical storage device.

11. The method of claim 10, wherein said substrate is a silicon substrate and forming said photovoltaic device comprises doping said silicon substrate with opposite dopants to form oppositely doped tub regions and p-n junctions in said doped silicon substrate, and further comprising depositing an antireflective layer on said surface, said antireflective layer having first and second electrical contacts formed therein that contact said oppositely doped tub regions, respectively.

12. The method of claim 10, wherein fabricating a storage device comprises fabricating a capacitor on said second side, and forming an antenna comprises locating said antenna on an outer surface of said capacitor, and further comprising anneal said photovoltaic device with a laser anneal.

13. The method of claim 12, wherein said capacitor is a trench capacitor.

14. The method of claim 10, wherein forming an antenna comprises forming said antenna in a “J” shape or a “C” shape configuration using an inkjet deposition process.

15. The method of claim 14, wherein forming said antenna comprises forming said antenna in said “C” shape configuration, which allows said antenna to receive radio frequency (RF) signals ranging from about 915 MHz to about 2.4 GHz and convert said RF signals into an electrical current.

16. The method of claim 10, wherein forming a photovoltaic device comprises depositing a cadmium sulfide (CdS) layer over said substrate and depositing a cadmium telluride (CdTe) layer on said CdS layer.

17. The method of claim 16, further comprising forming a low resistivity transparent conductive oxide (TCO) layer on said substrate, depositing said CdS layer on said TCO layer, depositing said CdTe layer on said CdS layer, depositing a metal layer on said CdTe layer.

18. The method of claim 17 further comprising forming a dielectric layer on said metal layer, and wherein said energy storage device is located on said dielectric layer.

19. A hybrid energy harvesting device, comprising:
a photovoltaic device having a substrate that forms a first side of said photovoltaic device, said substrate having a surface through which photons can pass to produce an electrical current within said photovoltaic device;
a capacitor located on a second side of said photovoltaic device that opposes said first side; and
an antenna located on one of said first or second sides of said photovoltaic device, said antenna having a “J” shape configuration or a “C” shape configuration, and said photovoltaic device and said antenna electrically coupled to said capacitor.

20. The hybrid energy harvesting device of claim 19, wherein said substrate is a doped silicon or silicon substrate doped with opposite dopants to form oppositely doped tube regions and pn junctions within said silicon or silicon substrate, and further comprising an antireflective layer located on said surface and having first and second electrical contacts formed therein that contact said oppositely doped tub regions, respectively.

21. The hybrid energy harvesting device of claim 19, wherein said capacitor is a trench capacitor.

22. The hybrid energy harvesting device of claim 19, wherein said antenna has said “C” shape configuration, which allows said antenna to receive radio frequency (RF) signals ranging from about 915 MHz to about 2.4 GHz and convert said RF signals into an electrical current.

23. The hybrid energy harvesting device of claim 19, further comprising a low resistivity transparent conductive oxide (TCO) layer located on said substrate, a cadmium sulfide (CdS) layer located on said TCO layer, a cadmium telluride (CdTe) layer located on said CdS layer, and a metal layer located on said CdTe layer.

24. The hybrid energy harvesting device of claim 23 further comprising a dielectric layer located on said metal layer, and wherein said energy storage device is located on said dielectric layer.

25. A sensor node, comprising.
a circuit board,
a hybrid energy harvesting device located on and electrically coupled to said circuit board and comprising:
a photovoltaic device having a substrate that forms a first side of said photovoltaic device, said substrate having a surface through which photons can pass to produce an electrical current within said photovoltaic device;
an electrical storage device located on a second side of said photovoltaic device that opposes said first side; and
an antenna located on one of said first or second sides of said photovoltaic device, said photovoltaic device and said antenna electrically coupled to said electrical storage device;
a solar conversion circuit located on and electrically coupled to said circuit board to electrically couple said solar conversion circuit to said photovoltaic device and said electrical storage device;
a radio frequency circuit located on and electrically coupled to said circuit board to electrically couple said radio frequency circuit to said antenna and said electrical storage device; and
a digital processing circuit located on and electrically coupled to said circuit board to electrically couple said digital processing circuit to said storage device.
